(19) United States
(12) Patent Application Publication
(10) Pub. No.: US 2025/0087464 A1
(43) Pub. Date: Mar. 13, 2025

(54) FOCUS RING ALIGNMENT APPARATUS

(71) Applicant: SAMSUNG ELECTRONICS CO., LTD., Suwon-si, Gyeonggi-do (KR)

(72) Inventors: Jaehyun SOH, Suwon-si (KR); Wookhyeon KWON, Suwon-si (KR); Chulwoo PARK, Suwon-si (KR); Dongkyu SHIN, Suwon-si (KR); Hoontaek LEE, Suwon-si (KR); Minnhoo CHOI, Suwon-si (KR); Yongwoo KIM, Suwon-si (KR); Jaehyun KIM, Suwon-si (KR); Hansol KIM, Suwon-si (KR); Deukho LEE, Suwon-si (KR); Junghyun CHO, Suwon-si (KR); Yangyeon CHU, Suwon-si (KR); Uzun KAAN, Suwon-si (KR)

(21) Appl. No.: 18/590,406

(22) Filed: Feb. 28, 2024

(30) Foreign Application Priority Data
Sep. 11, 2023 (KR) 10-2023-0120625

(51) Int. Cl. H01J 37/32

(52) U.S. Cl. CPC H01J 37/32642; H01J 2237/049; H01J 2237/1502

(57) ABSTRACT

An embodiment provides a focus ring alignment apparatus including a frame, a sensing member that is connected to the frame and is configured to acquire images of a focus ring within in a substrate processing apparatus, and an alignment module that is connected to the frame and is configured to move the focus ring to change a position of the focus ring.

### CROSS-REFERENCE TO RELATED APPLICATION

This application claims priority to and the benefit of Korean Patent Application No. 10-2023-0120625 filed in the Korean Intellectual Property Office on Sep. 11, 2023, the disclosure of which is incorporated herein by reference in its entirety.

### BACKGROUND OF THE INVENTION

### (a) Field of the Invention

The present disclosure relates to a focus ring alignment apparatus.

### (b) Description of the Related Art

In order to manufacture semiconductor devices, various processes such as photolithography, etching, ashing, ion implantation, thin film deposition, and cleaning are performed on a substrate to form a desired pattern on the substrate.

Among them, devices using plasma are used for dry etching and deposition. Generally, to form plasma, an electromagnetic field is formed in an inner space of a chamber, and the electromagnetic field excites a process gas provided in the chamber into a plasma state. In devices using plasma, a focus ring is used to control the density distribution of the plasma. The focus ring wears out during use and is replaced after being used for a certain period of time.

### SUMMARY OF THE INVENTION

Embodiments are to provide a focus ring alignment apparatus that may effectively adjust a position of a focus ring.

However, the objective of the present disclosure is not limited to the aforementioned one, and may be extended in various ways within the scope of the present disclosure.

An embodiment provides a focus ring alignment apparatus including a frame; at least one sensing member connected to the frame, wherein the at least one sensing member is configured to acquire images of a focus ring within a substrate processing apparatus; and at least one alignment module that is connected to the frame, wherein the at least one alignment module is configured to move the focus ring to change a position of the focus ring.

Another embodiment provides a focus ring alignment apparatus including a frame including a main frame portion having a circular outer circumference; at least one sensing member connected to the frame. wherein the at least one sensing member is configured to acquire images of a focus ring within a substrate processing apparatus; a plurality of alignment modules connected to the main frame portion in circumferentially spaced apart relationship, and wherein the plurality of alignment modules are radially spaced apart from a center of the main frame portion by a preset distance; and a controller configured to receive imaged data of the focus ring from the at least one sensing member, and to control the plurality of alignment modules to move the focus ring.

Another embodiment provides a focus ring alignment apparatus including a frame including a main frame portion having a circular outer circumference, and a support frame portion extending away from the main frame portion; at least one sensing member connected to the frame and configured to acquire images of imaging a space adjacent the main frame portion; a plurality of alignment modules connected to the main frame portion, wherein the plurality of alignment modules are in circumferentially spaced apart relationship, and are radially spaced apart from a center of the main frame portion by a preset distance; and a controller configured to receive imaged data from the at least one sensing member, to extract at least three feature points on a focus ring from the imaged data, to determine a position of the focus ring by deriving a circle passing through the at least three feature points, and to control the plurality of alignment modules to move the focus ring.

According to the embodiments, it is possible to provide a focus ring alignment apparatus that may effectively adjust a position of a focus ring.

### BRIEF DESCRIPTION OF THE DRAWINGS

FIG. 1 illustrates a focus ring alignment apparatus according to an embodiment.

FIG. 2 is a bottom perspective view of the focus ring alignment apparatus of FIG. 1.

FIG. 3 illustrates an alignment module of FIG. 1 and FIG. 2.

FIG. 4 illustrates a control relationship of a focus ring alignment apparatus according to an embodiment.

FIG. 5 illustrates a state in which a focus ring alignment apparatus according to an embodiment is installed in a substrate processing apparatus.

FIG. 6 illustrates a process in which a focus ring alignment apparatus senses a position of a focus ring.

FIG. 7 to FIG. 12 illustrate a process in which a position of a focus ring is corrected by an alignment module.

FIG. 13 to FIG. 16 illustrate operating states before and after an alignment member pushes a focus ring.

FIG. 17 illustrates an alignment member according to another embodiment.

FIG. 18 to FIG. 21 illustrate a state in which an alignment member pushes a focus ring according to another embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

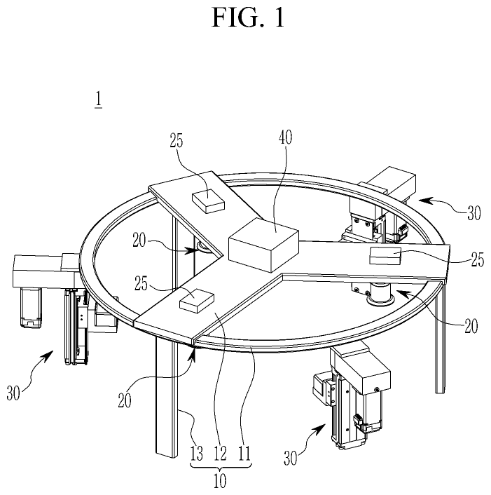

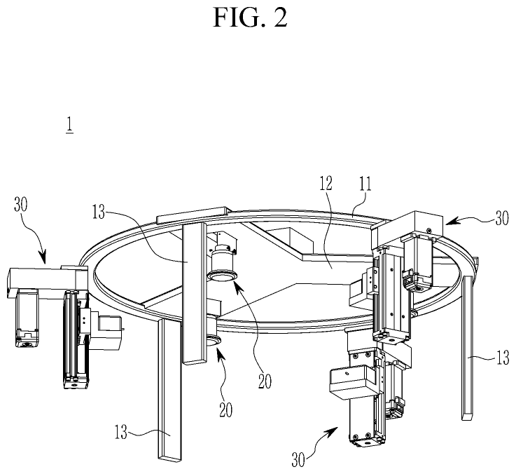

FIG. 1 illustrates a focus ring alignment apparatus 1 according to an embodiment, and FIG. 2 is a bottom perspective view of the focus ring alignment apparatus 1 of FIG. 1 viewed from below.

Referring to FIG. 1 and FIG. 2, the focus ring alignment apparatus 1 according to the embodiment includes a frame 10, a sensing member 20, an alignment module 30, and a controller 40.

The frame 10 has a predetermined volume. The frame 10 may include a main frame portion 11, an auxiliary frame portion 12, and a support frame portion 13.

The main frame portion 11 may be provided in a shape having an outer circumference corresponding to a circular shape. For example, the outer circumference of the main frame portion 11 may be provided to have a circular shape. In addition, the outer circumference of the main frame portion 11 may be configured to have a plurality of arcs spaced apart from each other. The main frame portion 11 may have a ring or annular structure so that an inner area thereof penetrates upward and downward.

The auxiliary frame portion 12 may be disposed in the inner area of the main frame portion 11. The auxiliary frame portion 12 may have a structure extending in a radial direction from an inner center of the main frame portion 11. A plurality of auxiliary frame portions 12 may be provided. The plurality of auxiliary frame portions 12 may be connected to each other at the inner center of the main frame portion 11 to have a radial structure. Central angles between the adjacent auxiliary frame portions 12 may correspond to each other (i.e., the angles between adjacent ones of the auxiliary frame portions 12 may be the same, such as 120 degrees for the illustrated embodiment with three auxiliary frame portions 12). FIG. 1 and FIG. 2 illustrate a case in which three auxiliary frame portions 12 are provided.

The support frame portion 13 may be provided to extend downward from the main frame portion 11. The support frame portion 13 has a preset length in the upward/downward direction. A plurality of support frame portions 13 may be provided and disposed to be spaced apart from each other along the circumferential direction of the main frame portion 11.

The sensing member 20 is connected to the frame 10. The sensing member 20 is provided to be able to image a space positioned below the main frame portion 11. As an example, the sensing member 20 may be provided as a camera, an image sensor, and the like

The sensing member 20 may be connected to a lower portion of the auxiliary frame portion 12.

The sensing member 20 may be connected to the frame 10 through a position adjustment member 25. The sensing member 20 may be disposed to be spaced apart from the center area of the main frame portion 11 by a preset distance in the radial direction. The position adjustment member 25 allows the position of the area to be imaged through the sensing member 20 to be adjusted. The position adjustment member 25 may adjust the direction of the sensing member 20 to adjust the position of the area imaged through the sensing member 20. For example, the position adjustment member 25 may move the sensing member 20 in the radial direction of the main frame portion 11 to adjust the position of the area imaged through the sensing member 20. In addition, the position adjustment member 25 may rotate the sensing member 20 about an axis in a direction intersecting the upward/downward direction to adjust the position of the area imaged through the sensing member 20. In addition, the position adjustment member 25 may move the sensing member 20 in the upward/downward direction with respect to the frame 10 to adjust the area of the area imaged by the sensing member 20.

A plurality of sensing members 20 may be provided. Each of the plurality of sensing members 20 may be disposed in one of the plurality of auxiliary frame portions 12. The plurality of sensing members 20 may be disposed spaced apart from each other on a circumference at a preset distance from the inner center of the main frame portion 11. FIG. 1 and FIG. 2 illustrate a case in which the sensing member 20 is disposed in each of the three auxiliary frame portions 12.

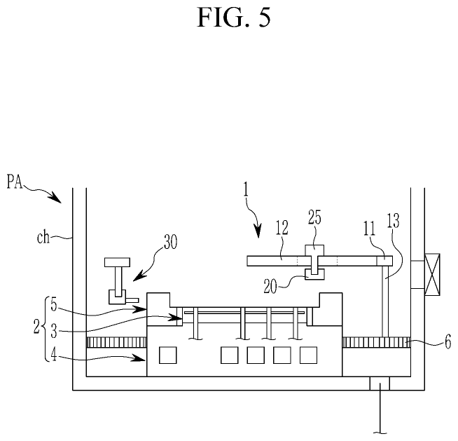

The alignment module 30 pushes a focus ring (5 in FIG. 5) to change a position of the focus ring 5. The alignment module 30 is connected to the frame 10. The alignment module 30 may be connected to a lower portion of the main frame portion 11. The alignment member 30 may be disposed to be spaced apart from the center area of the main frame portion 11 by a preset distance in the radial direction. A plurality of alignment modules 30 may be provided. At least three alignment modules 30 may be provided. The plurality of alignment modules 30 may be disposed to be spaced apart from each other along the circumferential direction of the main frame portion 11. The plurality of alignment modules 30 may be disposed spaced apart from each other on a circumference at a preset distance from the inner center of the main frame portion 11. Central angles between the adjacent alignment modules 30 may correspond to each other (i.e., the angles between adjacent ones of the alignment modules 30 may be the same, such as 120 degrees for the illustrated embodiment) As such, the alignment modules 30 may be equally spaced apart circumferentially around the main frame portion 11.

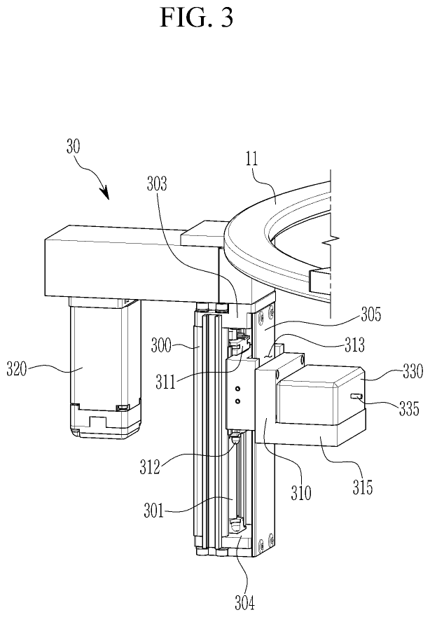

FIG. 3 illustrates the alignment module 30 of FIG. 1 and FIG. 2.

Referring to FIG. 3, the alignment module 30 may include a module body 300, an elevation member 310, an elevation driving member 320, and an alignment member 330.

The module body 300 is connected to the frame 10. The module body 300 may be connected to the main frame portion 11. The module body 300 may be coupled to the lower portion of the main frame portion 11. The module body 300 may extend downward from the lower surface of the main frame portion 11 by a preset length. A lower end of the module body 300 is disposed above a lower end of the support frame 10. An upper support portion 303 may be formed at an upper end portion of the module body 300. The upper support portion 303 may extend from the upper end portion of the module body 300 toward the center area of the main frame portion 11. A lower support portion 304 may be formed at a lower end portion of the module body 300. The lower support portion 304 may extend from the lower end portion of the module body 300 toward the center area of the main frame portion 11. The lower support portion 304 may face the upper support portion 303 in the upward/downward direction.

The elevation member 310 is connected to the module body 300 to be movable in the upward/downward direction. For example, an elevation guide portion 301 whose longitudinal direction faces the upward/downward direction may be disposed on one side of the module body 300. The elevation guide 301 may be disposed between the upper support portion 303 and the lower support portion 304. In addition, the elevation member 310 may be connected to the elevation guide portion 301 to be movable in the upward/downward direction. The elevation guide portion 301 may be provided as a guide rail, and may be through-inserted and connected to the elevation member 310 in the upward/downward direction. In addition, the elevation guide portion 301 may be provided as a guide rail, and the elevation member 310 may be connected to partially surround the outer circumference of the elevation guide portion 301.

An upper stopper 311 may be disposed on the upper portion of the elevation member 310. The upper stopper 311 may face the upper support portion 303 in the upward/downward direction. A lower stopper 312 may be disposed at the lower portion of the elevation member 310. The lower stopper 312 may face the lower support portion 304 in the upward/downward direction.

A sliding hole 313 may be formed through one side of the elevating member 310 in the upward/downward direction. An auxiliary guide portion 305 may be inserted and disposed in the sliding hole 313. The auxiliary guide portion 305 has a preset length in the upward/downward direction. A length of the auxiliary guide portion 305 in the upward/downward direction may correspond to a length of the module body 300 in the upward/downward direction. At least one of the upper and lower end portions of the auxiliary guide portion 305 may be coupled to the module body 300.

A portion of an area of the outer surface of the elevation member 310 are disposed to face the inner center area of the main frame portion 11. Hereinafter, the area from the outer surface of the elevation member 310 toward the inner center of the main frame portion 11 is referred to as an inner surface of the elevation member 310. A support portion 315 may be formed on at lower portion of the inner surface of the elevation member 310. The support portion 315 is disposed to extend from the lower portion of the inner surface of the elevation member 310 toward the inner center area of the main frame portion 11.

The elevation driving member 320 may be connected to one side of the module body 300. The elevation driving member 320 provides power for the elevation member 310 to move up and down with respect to the module body 300. For example, the elevation driving member 320 may be provided as a servo motor, and the like

The alignment member 330 is connected to the elevation member 310. That is, the alignment member 330 may be movably connected to the module body 300 in the upward/downward direction through the elevation member 310. The alignment member 330 is disposed in an area facing the inner center area of the main frame portion 11 in the elevation member 310. Accordingly, the alignment member 330 may be disposed to face the inner center area of the main frame portion 11. A bottom surface of the alignment member 330 may be disposed on an upper surface of the support portion 315.

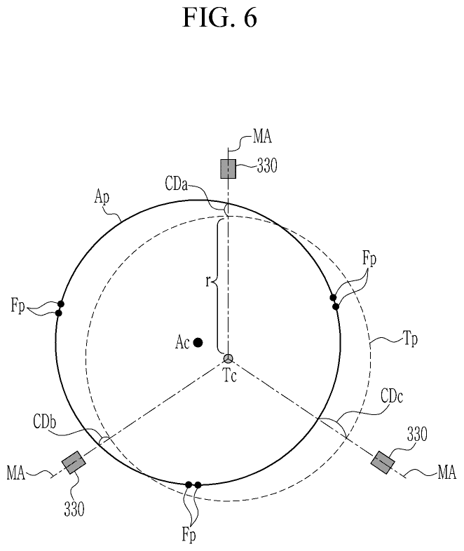

The alignment member 330 is provided to be movable toward the inner center area of the main frame portion 11 with respect to the elevation member 310. That is, a distance of the alignment member 330 spaced apart from the main frame portion 11 in the radial direction with respect to the inner center area of the main frame portion 11 may be adjusted. As an example, the alignment member 330 may be provided to have a cylindrical structure and the like to move toward the inner center area of the main frame portion 11 with respect to the elevation member 310. A movement axis (MA in FIG. 6) along which the alignment member 330 moves relative to the elevation member 310 may pass through the inner center area of the main frame portion 11. That is, a path along which the alignment member 330 moves with respect to the elevation member 310 may be in the radial direction with respect to the inner center area of the main frame portion 11.

A pressurizing portion or contact member 335 may extend from an area of the alignment member 330 (hereinafter referred to as an inner area of the alignment member 330) facing the inner center area (i.e., the center) of the annular main frame portion 11. The contact member 335 may extend from the inner area of the alignment member 330 toward (i.e., in a radial direction toward) the center of the annular main frame portion 11. The contact member 335 may have a rod shape (e.g., the contact member may be an elongate member).

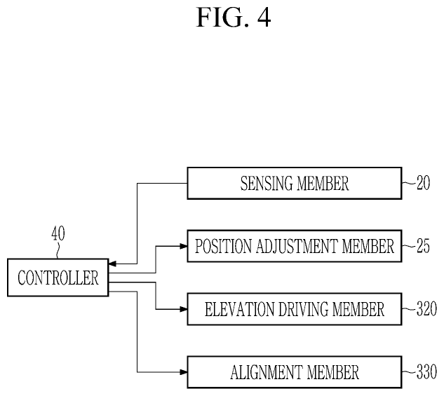

FIG. 4 illustrates a control relationship of the focus ring alignment apparatus 1 according to the embodiment.

Referring to FIG. 4, the controller 40 controls the operating states of the components of the focus ring alignment apparatus 1. For example, the controller 40 may be disposed on one side of the frame 10 (FIG. 1). In addition, the controller 40 is provided to be able to transmit and receive data with the components of the focus ring alignment apparatus 1 through wired or wireless communication, and may be disposed physically away from the frame 10.

The controller 40 may receive imaged data from the sensing member 20. The controller 40 may sense the position of focus ring 5 through the imaged data.

The controller 40 may operate the position adjustment member 25 to adjust the direction in which the sensing member 20 faces. Accordingly, the position at which the sensing member 20 images may be adjusted. In addition, the controller 40 may operate the position adjustment member 25 to move the sensing member 20 in the upward/downward direction with respect to the frame 10.

The controller 40 may control the alignment module 30 to cause the alignment module 30 to push the focus ring 5.

The controller 40 may operate the elevation driving member 320 to adjust the vertical position of the elevation member 310 with respect to the module body 300. That is, the controller 40 may operate the elevation driving member 320 to adjust the vertical position of the alignment member 330 with respect to the module body 300.

The controller 40 may operate the alignment member 330 to adjust the position of the alignment member 330 with respect to the elevation member 310. That is, the controller 40 may operate the alignment member 330 to adjust the position of the alignment member 330 with respect to the module body 300. Accordingly, the position of the alignment member 330 in the radial direction with respect to the inner center area of the main frame 10 may be adjusted, so that the alignment member 330 may push the focus ring 5.

FIG. 5 illustrates a state in which the focus ring alignment apparatus 1 according to the embodiment is installed in a substrate processing apparatus PA

Referring to FIG. 5, the focus ring alignment apparatus 1 may be installed and used in the substrate processing apparatus PA. The substrate processing apparatus PA processes a substrate using plasma. For example, the substrate processing apparatus PA may perform an etching process, a deposition process, and the like using excited plasma.

The substrate processing apparatus PA includes a chamber ch and a support member 2.

The chamber ch provides a processing space within which a substrate processing process is performed. The chamber ch has an internal processing space and is provided in a sealed shape. The focus ring alignment apparatus 1 may be installed inside the chamber ch after the upper portion of the chamber ch is opened.

The support member 2 is disposed inside the chamber ch. The support member 2 may be disposed at a lower portion of the processing space. The support member 2 supports the substrate during the substrate processing process.

The support member 2 includes a dielectric plate 3, a body 4, and a focus ring 5.

The dielectric plate 3 is disposed on an upper portion of the support member 2. The dielectric plate 3 may be provided to have a plate structure with a predetermined thickness. An outer circumference of the dielectric plate 3 may be circular. The dielectric plate 3 is provided as a dielectric substance. A substrate is disposed on the upper surface of the dielectric plate 3. An area of the upper surface of the dielectric plate 3 is provided to be smaller than that of the substrate. The upper surface of the dielectric plate 3 may have a smaller radius than the substrate.

The body 4 is disposed at the lower portion of the support member 2. The dielectric plate 3 may be disposed on the upper portion of the body 4. For example, the dielectric plate 3 may be attached to the body 4 by an adhesive layer. The upper portion of the body 4 may be stepped so that the center area thereof is disposed higher than the edge area thereof. The upper central area of the body 4 can be provided to have a shape corresponding to the bottom surface of the dielectric plate 3. The dielectric plate 3 may be disposed above the upper central area of the body 4.

The focus ring 5 may be disposed in the upper outer area of the support member 2. The focus ring 5 may be disposed on the outer circumference of the dielectric plate 3. The focus ring 5 is provided in a ring structure. Accordingly, the focus ring 5 has an inner surface facing the support member 2 and an outer surface facing the opposite direction of the support member 2. The focus ring 5 may be disposed on the upper edge area of the body 4. The focus ring 5 improves the uniformity of density distribution of plasma. The focus ring 5 may be worn by contact with the substrate or an electromagnetic force acting on the focus ring 5 during use of the focus ring 5. As the wear of the focus ring 5 increases, the performance of controlling the density distribution of plasma deteriorates. Accordingly, the focus ring 5 is replaced after being used for a certain period of time or a certain number of times.

A baffle 6 may be disposed between the support member 2 and the inner surface of the chamber ch. A plurality of holes may be formed through the baffle 6 in the upward/downward direction. The flow of process gas may be adjusted depending on the shape of the baffle 6 and the shape of the hole formed in the baffle 6.

In order to improve the operating characteristics of the focus ring 5, the focus ring 5 must be correctly aligned with respect to the dielectric plate 3. Specifically, there is a gap between the inner surface of the focus ring 5 and the outer circumference of the dielectric plate 3. In order for the focus ring 5 to be correctly aligned with respect to the dielectric plate 3, the gap between the focus ring 5 and the dielectric plate 3 needs to be uniform depending on area. That is, it is desirable that the center of the focus ring 5 and the center of the dielectric plate 3 coincide, so that the focus ring 5 and the dielectric plate 3 form a concentric circle.

Accordingly, the focus ring alignment apparatus 1 according to the embodiment adjusts the position of the focus ring 5 during the replacement process of the focus ring 5, so that the focus ring 5 is aligned with the dielectric plate 3. The focus ring alignment apparatus 1 may be installed in the substrate processing apparatus PA in such a way that the lower end portion of the frame 10 is fixed to the lower portion of the processing space. For example, in the focus ring alignment apparatus 1, the support frame portion 13 may be disposed on the baffle 6 and installed in the substrate processing apparatus PA. The lower end portion of the frame 10 may have a shape corresponding to the area installed in the substrate processing apparatus PA. Accordingly, when the lower end portion of the frame 10 is fixed to the substrate processing apparatus PA, the focus ring alignment apparatus 1 may be installed in an aligned form with respect to the support member 2.

When the focus ring alignment apparatus 1 is installed in the substrate processing apparatus PA, the main frame portion 11 may be disposed above the support member 2. In addition, when the focus ring alignment apparatus 1 is installed in the substrate processing apparatus PA, the sensing member 20 may be disposed above the area in which the focus ring 5 is disposed. In addition, when the focus ring alignment apparatus 1 is installed in the substrate processing apparatus PA, the alignment module 30 may be disposed adjacent to the focus ring 5.

FIG. 6 illustrates a process in which the focus ring alignment apparatus 1 senses the position of the focus ring.

Referring to FIG. 6, the focus ring alignment apparatus 1 may sense the position of the focus ring 5 through the sensing member 20.

Specifically, the controller 40 senses the position of the focus ring 5 through the imaged data received from the sensing member 20. The controller 40 extracts a feature point Fp on the focus ring 5 from the imaged data received from the sensing member 20. The feature point Fp may be a point on the focus ring 5. For example, the feature point Fp may be a point on the outer edge of the focus ring 5. The outer edge of the focus ring 5 may be an upper end portion of the outer surface of the focus ring 5.

The controller 40 extracts at least three feature points Fp through the imaged data received from the sensing member 20. Each of the feature points Fp is a corresponding point on the focus ring 5. For example, each of the feature points Fp may be a point on the outer edge of the focus ring 5. The feature points Fp may be disposed to be spaced apart from each other along the circumferential direction of the focus ring 5.

When a plurality of sensing members 20 are provided, the number of the feature points Fp extracted from the imaged data received from respective sensing members 20 may be the same or different. In addition, the controller 40 may extract two feature points Fp from the imaged data provided by one sensing member 20 with the minimum pixel size therebetween. FIG. 6 illustrates a case in which three sensing members 20 are provided and two feature points Fp are extracted from the imaged data received from each sensing member 20.

Thereafter, the controller 40 derives a circle passing through the extracted feature points Fp to sense an actual position Ap of the focus ring 5. The controller 40 may use the least square method (LSM) to derive the circle passing through the feature points Fp. The circle derived through the feature points Fp becomes the actual position Ap of the focus ring 5. In addition, the controller 40 may derive an actual center Ac that is the center of the actual position Ap together. When the feature points Fp are points on the outer edge of the focus ring 5, the actual position Ap becomes the position of the outer edge of the focus ring 5 sensed by the controller 40.

The controller 40 stores data about a target position Tp at which the focus ring 5 will be aligned. The target position Tp is data on the coordinates at which the focus ring 5 is disposed when the focus ring 5 is correctly aligned with respect to the dielectric plate 3. The target position Tp is provided as a circular shape corresponding to the actual position Ap. A radius r of the target position Tp may be provided to be the same as the radius of the actual position Ap. For example, when the feature point Fp is a point on the outer edge of the focus ring 5, the radius r of the actual position Ap may be the radius from the center of the focus ring 5 to the outer edge of the focus ring 5.

In addition, the controller 40 stores data on the target center Tc, which is the center of the target position Tp. When the focus ring alignment apparatus 1 is installed in the substrate processing apparatus PA, the target center Tc may be aligned with the center of the dielectric plate 3. The target center Tc may be disposed in the inner center area of the main frame portion 11.

The movement axis MA along which the alignment member 330 moves with respect to the elevation member 310 may be aligned with the radial direction of the target position Tp. That is, when the focus ring alignment apparatus 1 is correctly installed in the substrate processing apparatus PA, the movement axis MA of the alignment member 330 may pass through the center of the target center Tc and the center of the dielectric plate 3. When the focus ring alignment apparatus 1 is correctly installed in the substrate processing apparatus PA, the end portion of the contact member 335 facing the target center Tc may be disposed on the movement axis MA.

The controller 40 may calculate correction distances CDa, CDb, and CDc through a deviation between the actual position Ap and the target position Tp. The correction distance CDa, CDb, and CDc may be calculated as the deviation between the actual position Ap and the target position Tp in the radius direction of the target position Tp. In addition, the correction distance CDa, CDb, and CDc may be calculated as the deviation between the actual position Ap and the target position Tp along the movement axis MA of the alignment member 330. The same number of the correction distances CDa, CDb, and CDc as the number of alignment modules 30 may be calculated. The correction distances CDa, CDb, and CDc may be calculated on the movement axis MA of the alignment member 330. The correction distance CDa, CDb, and CDc may be calculated by subtracting the radius r of the target position Tp from the distance from the target center Tc to the actual position Ap. The radius r of the target position Tp corresponds to the radius of the actual position Ap. That is, when the feature point Fp is a point on the outer edge of the focus ring 5, the radius r of the target position Tp may correspond to the radius from the center of the focus ring 5 to the outer edge of the focus ring 5.

The correction distances CDa, CDb, and CDc may have negative values in an area in which the actual position Ap is disposed inside the target position Tp. In addition, the correction distances CDa, CDb, and CDc may have positive values in an area in which the actual position Ap is disposed outside the target position Tp. In addition, the correction distance CDa, CDb, and CDc become 0 when the actual position Ap is disposed on the target position Tp.

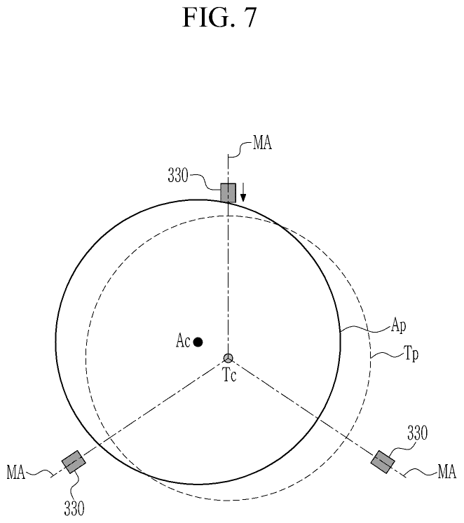

FIG. 7 to FIG. 12 illustrate a process in which the position of the focus ring 5 is corrected by the alignment module 30.

Referring to FIG. 7, the controller 40 may determine whether position correction of the focus ring 5 is necessary through the deviation between the target position Tp and the actual position Ap.

When the distance between the target center Tc and the actual center Ac is greater than a preset value, the controller 40 may determine that the position correction of the focus ring 5 is necessary. In addition, when the distance between the target center Tc and the actual center Ac is smaller than a preset value, the controller 40 may determine that the focus ring 5 is correctly disposed and that the position correction is not necessary.

In addition, the controller 40 may determine that the position correction of the focus ring 5 is necessary when at least one of the plurality of correction distances CDa, CDb, and CDc is greater than a preset value. In addition, when the plurality of correction distances CDa, CDb, and CDc are all smaller than a preset value, the controller 40 may determine that the focus ring 5 is correctly disposed and that the position correction is not necessary.

In addition, the controller 40 may determine that the position correction of the focus ring 5 is necessary when the dispersion or standard deviation of the plurality of correction distances CDa, CDb, and CDc is greater than a preset value. In addition, when the dispersion or standard deviation of the plurality of correction distances CDa, CDb, and CDc is smaller than a preset value, the controller 40 may determine that the focus ring 5 is correctly disposed and that the position correction is not necessary.

When it is determined that the position correction of the focus ring 5 is necessary, the controller 40 moves the alignment member 330 disposed on the movement axis MA on which the correction distances CDa, CDb, and CDc are calculated to have positive values in the direction of the target center Tc (that is, the actual location Ap and the target location Tp). Accordingly, the alignment member 330 contacts the focus ring 5 and then pushes the focus ring 5 in the direction of the target center Tc. Accordingly, on the movement axis MA, the actual position Ap (and the focus ring 5) moves in the direction of the target center Tc.

When several of the plurality of correction distances CDa, CDb, and CDc have positive values, the controller 40 may move the alignment member 330 disposed on the movement axis MA in which the correction distances CDa, CDb, and CDc greater than the preset value are calculated.

In addition, when several of the correction distances CDa, CDb, and CDc that have positive values and are greater than the preset value, the controller 40 may move the alignment member 330 disposed on the movement axis MA where one of the plurality of correction distances CDa, CDb, and CDc that are greater than the preset value is calculated.

In addition, when several of the correction distances CDa, CDb, and CDc that have positive values and are greater than the preset value, the controller 40 may move the alignment member 330 disposed on the movement axis MA where the correction distance CDa, CDb, or CDc having the largest value among the plurality of correction distances CDa, CDb, and CDc greater than the preset value is calculated.

In addition, when several of the correction distances CDa, CDb, and CDc that have positive values and are greater than the preset value, the controller 40 may move the alignment member 330 disposed on the movement axis MA where the correction distance CDa, CDb, or CDc having the smallest value among the plurality of correction distances CDa, CDb, and CDc greater than the preset value is calculated.

The alignment member 330 may move the focus ring 5 and the actual position Ap on the movement axis MA in the direction of the target center Tc by the correction distance CDa, CDb, or CDc. That is, when the feature point Fp is a point on the outer edge of the focus ring 5, the alignment member 330 may be moved so that the end portion thereof facing the target center Tc is disposed on the target position Tp. In addition, the feature point Fp may be disposed at a preset distance from the outer edge of the focus ring 5 toward the center of the focus ring 5. In this case, the alignment member 330 may be moved so that the end portion thereof facing the target center Tc is disposed on a position spaced radially from the target position Tp by the distance to the feature point Fp and the outer edge of the focus ring 5.

As the alignment member 330 pushes the focus ring 5, the actual center Ac moves in the direction of the target center Tc, so that the distance between the actual center Ac and the target center Tc may be closer than before the alignment member 330 pushes the focus ring 5.

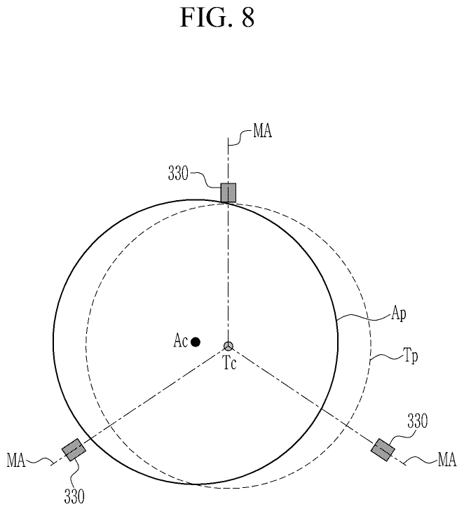

Referring to FIG. 8, after the alignment member 330 pushes the focus ring 5, the focus ring alignment apparatus 1 may sense the position of the focus ring 5 again through the sensing member 20. That is, through the method described above with reference to FIG. 6, the controller 40 senses the position of the focus ring 5 through the imaged data received from the sensing member 20.

In addition, using the method described above with reference to FIG. 6, the controller 40 may calculate the correction distances CDa, CDb, and CDC through the actual position Ap and the target position Tp.

In addition, using the method described above with reference to FIG. 7, the controller 40 may determine whether position correction of the focus ring 5 is necessary through the deviation between the target position Tp and the actual position Ap.

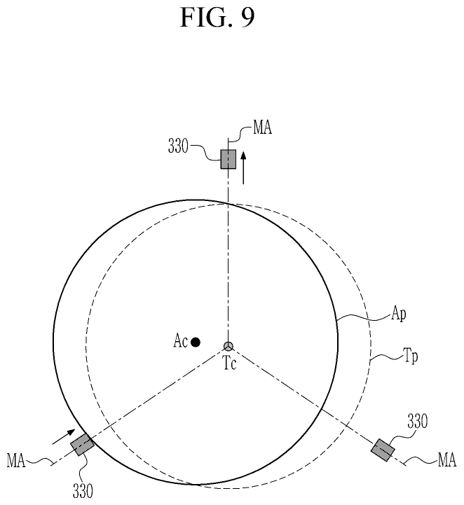

Referring to FIG. 9, when it is determined that the position correction of the focus ring 5 is necessary, the controller 40 moves the alignment member 330 disposed on the movement axis MA on which the correction distances CDa, CDb, and CDc are calculated to have positive values in the direction of the target center Tc (that is, the actual location Ap and the target location Tp).

Accordingly, the alignment member 330 contacts the focus ring 5 and then pushes the focus ring 5 in the direction of the target center Tc.

In FIG. 7, on the movement axis MA passing through the alignment member 330 that pushes the focus ring 5, the actual position Ap may be disposed on the target position Tp. In addition, in FIG. 7, on the movement axis MA passing through the alignment member 330 that pushes the focus ring 5, the actual position Ap may be disposed adjacent to the target position Tp. In addition, the controller 40 may move the alignment member 330 disposed on the movement axis MA for which the compensation distance CDa, CDb, or CDc greater than the preset value is calculated. Accordingly, the alignment member 330 that moves to push the focus ring 5 may be different from the alignment member 330 that previously pushed the focus ring 5 among the plurality of alignment members 330. Before the alignment member 330 pushes the focus ring 5, the alignment member 330 that previously pushed the focus ring 5 may move in the opposite direction of the target center Tc to be disposed to be spaced apart from the focus ring 5.

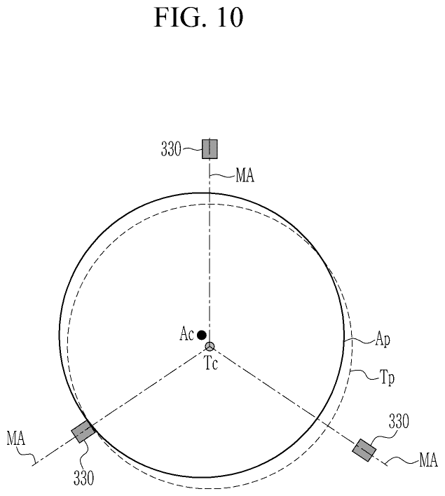

Referring to FIG. 10, after the alignment member 330 pushes the focus ring 5, the focus ring alignment apparatus 1 may sense the position of the focus ring 5 again through the sensing member 20. That is, through the method described above with reference to FIG. 6, the controller 40 senses the position of the focus ring 5 through the imaged data received from the sensing member 20.

In addition, using the method described above with reference to FIG. 6, the controller 40 may calculate the correction distances CDa, CDb, and CDC through the actual position Ap and the target position Tp.

In addition, using the method described above with reference to FIG. 7, the controller 40 may determine whether position correction of the focus ring 5 is necessary through the deviation between the target position Tp and the actual position Ap.

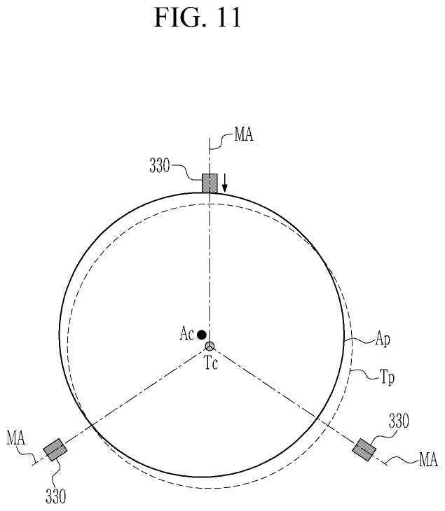

Referring to FIG. 11, when it is determined that the position correction of the focus ring 5 is necessary, the controller 40 moves the alignment member 330 disposed on the movement axis MA on which the correction distances CDa, CDb, and CDc are calculated to have positive values in the direction of the target center Tc (that is, the actual location Ap and the target location Tp).

Accordingly, the alignment member 330 contacts the focus ring 5 and then pushes the focus ring 5 in the direction of the target center Tc.

In FIG. 9, on the movement axis MA passing through the alignment member 330 that pushes the focus ring 5, the actual position Ap may be disposed on the target position Tp. In addition, in FIG. 9, on the movement axis MA passing through the alignment member 330 that pushes the focus ring 5, the actual position Ap may be disposed adjacent to the target position Tp. In addition, the controller 40 may move the alignment member 330 disposed on the movement axis MA for which the compensation distance CDa, CDb, or CDc greater than the preset value is calculated. Accordingly, the alignment member 330 that moves to push the focus ring 5 may be different from the alignment member 330 that previously pushed the focus ring 5 among the plurality of alignment members 330. Before the alignment member 330 pushes the focus ring 5, the alignment member 330 that previously pushed the focus ring 5 may move in the opposite direction of the target center Tc to be disposed to be spaced apart from the focus ring 5.

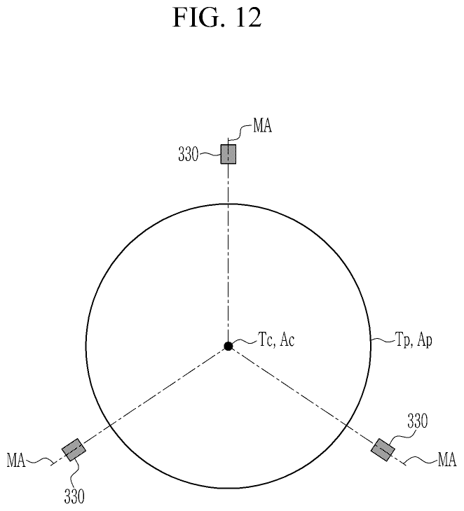

Referring to FIG. 12, the controller 40 may determine whether position correction of the focus ring 5 is necessary through the deviation between the target position Tp and the actual position Ap. Additionally, when the controller 40 determines that the position correction of the focus ring 5 is necessary, the controller 40 may move the alignment member 330 to align the focus ring 5. That is, the position correction of the focus ring 5 described above with reference to FIG. 6 to FIG. 11 may be repeatedly performed until the deviation between the target position Tp and the actual position Ap becomes smaller than a preset value. In addition, when the deviation between the target position Tp and the actual position Ap is smaller than the preset value, it is determined that the focus ring 5 is correctly disposed, and the position correction of the focus ring 5 may terminated.

When the position correction is completed, the controller 40 may move the alignment member 330 in the direction opposite to the target center Tc so that the alignment member 330 may be spaced apart from the focus ring 5.

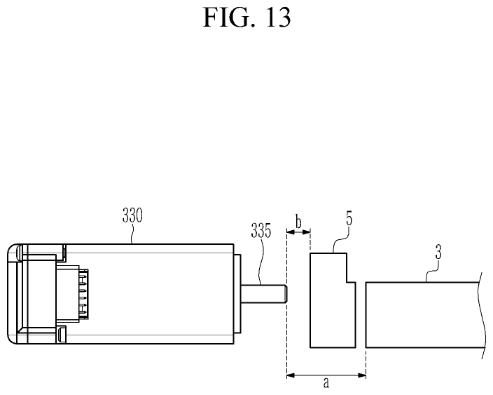

FIG. 13 to FIG. 16 illustrate operating states before and after the alignment member 330 pushes the focus ring 5.

FIG. 13 illustrates a state in which the alignment member 330 is disposed in a standby position.

Referring to FIG. 13, when the alignment member 330 moves in the opposite direction of the target center Tc, it is disposed in the standby position. That is, the alignment member 330 may be disposed in the standby position when it is not operating to push the focus ring 5. When the alignment member 330 is disposed in the standby position, the end portion of the alignment member 330 facing the target center Tc may be spaced apart from the outer surface of the dielectric plate 3 by a safety distance (a). That is, the contact member 335 of the alignment member 330 and the outer surface of the dielectric plate 3 may be spaced apart by the safety distance (a).

The safety distance (a) may be provided to be greater than the thickness between the inner and outer surfaces of the focus ring 5 by a preset length. Accordingly, when the alignment member 330 is disposed in the standby position, a safety gap (b) is formed between the end portion of the alignment member 330 facing the target center Tc and the outer surface of the focus ring 5. Through the safety gap (b), when the focus ring alignment apparatus 1 is installed in the substrate processing apparatus PA, the alignment member 330 and the focus ring 5 may be prevented from colliding.

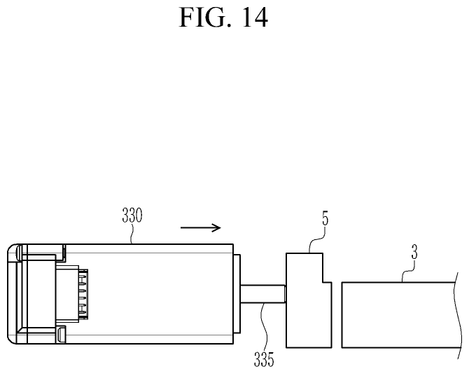

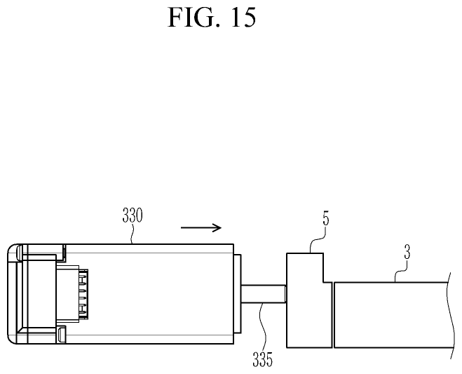

FIG. 14 illustrates a state in which the alignment member 330 is moved in the direction of the target center Tc to be adjacent to the focus ring 5, and FIG. 15 illustrates a state in which the alignment member 330 performs position correction of the focus ring 5.

Referring to FIG. 14 and FIG. 15, when the alignment member 330 in the standby position is moved in the direction of the target center (Tc) so that the actual position Ap is moved to the target position Tp on the movement axis MA, the controller 40 may stop or decelerate the alignment member 330 once.

Before pushing the focus ring 5 through the alignment member 330, the controller 40 may move the alignment member 330 to be adjacent to the focus ring 5 in the direction of the target center Tc. Accordingly, the alignment member 330 stops or decelerates at a position where a separation distance from the focus ring 5 is smaller than the safety gap (b). For example, the controller 40 may move the alignment member 330 in the direction of the target center Tc by the safety gap (b) so that the alignment member 330 is in contact with the focus ring 5, and then stop the alignment member 330. When the feature point Fp is a point on the outer edge of the focus ring 5, the controller 40 may move the alignment member 330 by a value obtained by subtracting the correction distance CDa, CDb, or CDc from the separation distance between the alignment member 330 at the standby position and the target position Tp. Thereafter, the controller 40 may move the alignment member 330 in contact with the focus ring 5 again by the correction distance CDa, CDb, or CDc. Accordingly, when contact between the focus ring 5 and the alignment member 330 occurs, the impact occurring between the focus ring 5 and the alignment member 330 may be reduced.

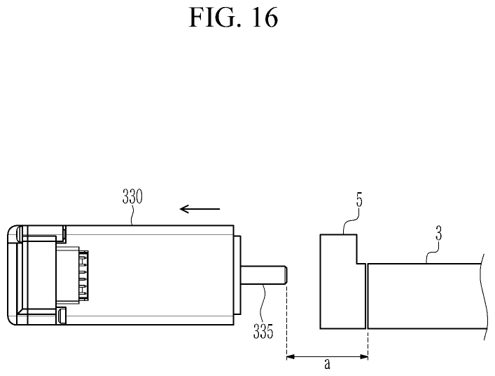

FIG. 16 illustrates a state in which the alignment member 330 returns to the standby position.

Referring to FIG. 16, when the alignment member 330 pushes the focus ring 5 to move the actual position Ap on the movement axis MA to the target position Tp, the controller 40 may return the alignment member 330 to the standby position by moving it in a direction opposite to the target center Tc.

According to the focus ring alignment apparatus 1 according to the embodiment, the position of the focus ring 5 may be precisely adjusted. Accordingly, the focus ring 5 is aligned with the dielectric plate 3, and the process efficiency of the substrate processing apparatus PA is improved.

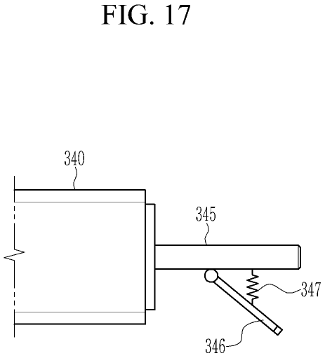

FIG. 17 illustrates an alignment member 340 according to another embodiment.

Referring to FIG. 17, a first contact member 345 may be disposed in an area of the alignment member 340 (hereinafter referred to as an inner area of the alignment member 340) facing the inner center area of the main frame portion 11. The first contact member 345 may extend from the inner area of the alignment member 340 toward the inner center area of the main frame portion 11. A length direction of the first contact member 345 may pass through the center of the annular main frame portion 11. The length direction of the first contact member 345 may be disposed on the movement axis MA (i.e., co-linear with the movement axis MA). The length direction of the first contact member 345 may pass through the target center Tc.

An auxiliary or second contact member 346 may be movably connected to the first contact member 345. The auxiliary contact member 346 is disposed below the first contact member 345, and one end portion thereof is rotatably connected to the first contact member 345 about an axis intersecting the upward/downward direction. The other end portion of the auxiliary contact member 346 is oriented to face the center of the annular main frame portion 11. The other end of the auxiliary contact member 346 may be positioned farther from the center of the annular main frame portion 11 than the end portion of the first contact member 345 facing the center of the annular main frame portion 11.

An elastic or biasing member, such as a spring, 347 may be connected between the first contact member 345 and the auxiliary contact member 346. The elastic member 347 may apply a downward force to the auxiliary contact member 346.

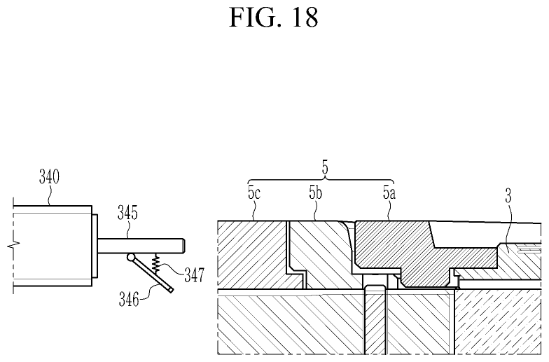

FIG. 18 to FIG. 21 illustrate a state in which the alignment member 340 pushes the focus ring 5 according to another embodiment.

A process in which the alignment member 340 pushes the focus ring 5 according to another embodiment will be described with reference to FIG. 18 to FIG. 21.

Referring to FIG. 18, the focus ring 5 may include an inner ring 5a, a middle ring 5b, and an outer ring 5c.

The inner ring 5a is disposed on the outer circumference of the dielectric plate 3, and the inner side surface of the inner ring 5a is disposed to face the outer side surface of the dielectric plate 3.

The middle ring 5b is disposed on the outer circumference of the inner ring 5a, and the inner side surface of the middle ring 5b is disposed to face the outer side surface of the inner ring 5a.

The outer ring 5c is disposed on the outer circumference of the middle ring 5b, and the inner side surface of the outer ring 5c is disposed to face the outer side surface of the middle ring 5b.

The alignment member 340 may adjust the position of the focus ring 5 with respect to the dielectric plate 3 by pushing the outer side surface of the focus ring 5. That is, the alignment member 340 may be disposed at a height corresponding to the focus ring 5 to push the outer ring 5c in the direction of the target center Tc. To this end, the controller 40 may control the elevation driving member 320 to position the elevation member 310 and the alignment member 340 at a height corresponding to the focus ring 5. Additionally, the controller 40 may control the alignment member 340 to move the alignment member 340 on the movement axis MA. Accordingly, the alignment member 340 may push the outer ring 5c, and the focus ring 5 including the outer ring 5c moves. The method by which the controller 40 moves the alignment member 340 to move the focus ring 5 and the actual position Ap is the same as or similar to the method described above with reference to FIG. 6 to FIG. 16, so repeated descriptions are omitted.

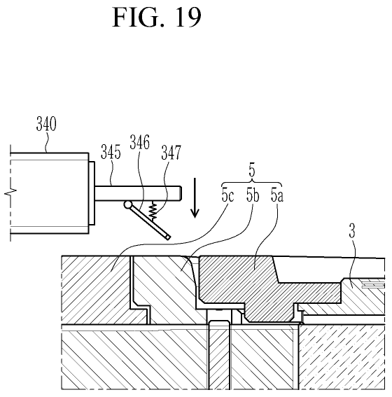

Referring to FIG. 19, the controller 40 may control the elevation driving member 320 to position the elevation member 310 and the alignment member 340 above the focus ring 5. Additionally, the controller 40 may control the alignment member 340 to position the auxiliary contact member 346 to face the middle ring 5b up and down (i.e., to position the auxiliary contact member 346 over the middle ring 5b, as illustrated).

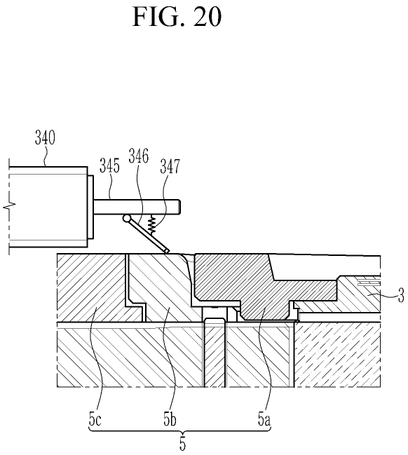

Referring to FIG. 20, the controller 40 may then control the elevation driving member 320 to lower the elevation member 310 and the alignment member 340. As the alignment member 340 descends, the auxiliary contact member 346 comes into contact with the upper surface of the middle ring 5b. Additionally, the elastic member 347 may push the auxiliary contact member 346 downward.

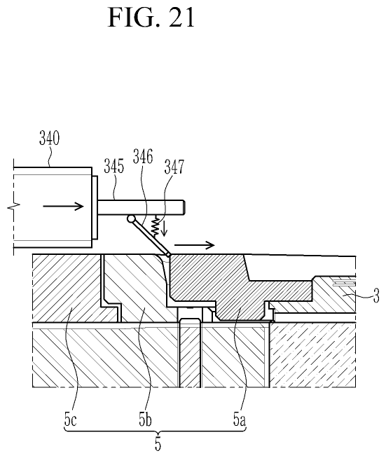

Referring to FIG. 21, the controller 40 then controls the alignment member 340 so that the alignment member 340 moves in the direction of the target center Tc. Accordingly, the auxiliary contact member 346 contacts the upper end edge of the inner ring 5a and then pushes the inner ring 5a.

In this case, the controller 40 senses the position of the inner ring 5a through the imaged data received from the sensing member 20. That is, the controller 40 extracts a feature point Fp on the inner ring 5a from the imaged data received from the sensing member 20. In addition, the controller 40 senses the actual position Ap of the inner ring 5a through the feature point Fp. Additionally, the controller 40 stores the target position Tp at which the inner ring 5a will be aligned.

The method by which the controller 40 senses the actual position Ap of the inner ring 5a and the method of calculating the correction distances CDa, CDb, and CDc through the actual position Ap and the target position Tp are the same as or similar to those in FIG. 6, so repeated descriptions are omitted. Additionally, the method by which the controller 40 moves the alignment member 340 to move the actual position Ap of the inner ring 5a to the target position Tp is the same as or similar to the method described above with reference to FIG. 6 to FIG. 16, so repeated descriptions are omitted.

The alignment member 340 according to another embodiment may perform position correction by individually moving only the inner ring 5a.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

### DESCRIPTION OF SYMBOLS

10: frame
11: main frame portion
12: auxiliary frame portion
13: support frame portion
20: sensing member
25: position adjustment member
30: alignment module
40: controller
300: module body
310: elevation member
320: elevation driving member
330: alignment member

What is claimed is:

1. A focus ring alignment apparatus comprising:
a frame;
at least one sensing member connected to the frame, wherein the at least one sensing member is configured to acquire images of a focus ring within a substrate processing apparatus; and
at least one alignment module connected to the frame, wherein the at least one alignment module is configured to move the focus ring to change a position of the focus ring.

2. The focus ring alignment apparatus of claim 1, wherein
the frame comprises a main frame portion having a circular outer circumference, and
wherein the at least one alignment module is connected to the main frame portion.

3. The focus ring alignment apparatus of claim 2, wherein
the at least one alignment module comprises a plurality of alignment modules, and wherein the plurality of alignment modules are connected to the main frame portion in circumferentially spaced apart relationship, and wherein the plurality of alignment modules are radially spaced apart from a center of the main frame portion by a preset distance.

4. The focus ring alignment apparatus of claim 2, wherein
the at least one alignment module comprises:
a module body connected to the main frame portion; and
an alignment member connected to the module body, wherein the alignment member is movable toward a center of the main frame portion.

5. The focus ring alignment apparatus of claim 4, wherein
the at least one alignment module further comprises:
an elevation member movably connected to the module body, wherein the elevation member is configured to move in opposite first and second directions relative to the main frame portion, and
wherein the alignment member is connected to the module body via the elevation member.

6. The focus ring alignment apparatus of claim 4, wherein
the alignment member is configured to move along a movement axis that passes through the center of the main frame portion.

7. The focus ring alignment apparatus of claim 4, wherein
the alignment member comprises a rod-shaped contact member that is oriented toward the center of the main frame portion.

8. The focus ring alignment apparatus of claim 7, wherein
the alignment member further comprises an auxiliary contact member movably connected to the contact member; and
a biasing member between the contact member and the auxiliary contact member.

9. The focus ring alignment apparatus of claim 2, wherein
the main frame portion has an annular structure, and
wherein the frame further comprises an auxiliary frame portion within an inner area of the main frame portion.

10. The focus ring alignment apparatus of claim 9, wherein
the at least one sensing member is connected to the auxiliary frame portion.

11. The focus ring alignment apparatus of claim 2, wherein
the at least one sensing member comprises a plurality of sensing members, and wherein the plurality of sensing members are in circumferentially spaced apart relationship, and are radially spaced apart from a center of the main frame portion by a preset distance.

12. The focus ring alignment apparatus of claim 1, further comprising
a controller configured to receive imaged data of the focus ring from the at least one sensing member, and to control the at least one alignment module to move the focus ring.

13. The focus ring alignment apparatus of claim 12, wherein
the controller is further configured to extract at least three feature points on the focus ring from the imaged data and then determine an actual position of the focus ring by deriving a circle passing through a plurality of the feature points.

14. The focus ring alignment apparatus of claim 13, wherein
the controller is further configured to store data about a target position for the focus ring, and to move the focus ring via the at least one alignment module so that a deviation between the target position and the actual position is smaller than a preset value.

15. The focus ring alignment apparatus of claim 14, wherein
the controller is further configured to control the at least one alignment module to move the focus ring by a correction distance, and
wherein the correction distance is a value obtained by subtracting a radius of the target position from a distance from a center of the target position to the actual position.

16. A focus ring alignment apparatus comprising:
a frame comprising a main frame portion having a circular outer circumference;
at least one sensing member connected to the frame, wherein the at least one sensing member is configured to acquire images of a focus ring within a substrate processing apparatus;
a plurality of alignment modules connected to the main frame portion in circumferentially spaced apart relationship, and wherein the plurality of alignment modules are radially spaced apart from a center of the main frame portion by a preset distance; and
a controller configured to receive imaged data of the focus ring from the at least one sensing member, and to control the plurality of alignment modules to move the focus ring.

17. The focus ring alignment apparatus of claim 16, wherein
each of the plurality of alignment modules comprises:
a module body connected to the main frame portion; and
an alignment member connected to the module body, wherein the alignment member is movable toward the center of the main frame portion,
wherein the controller is further configured to store data about a target position for the focus ring, and
wherein a movement axis along which the alignment member moves passes through a center of the target position.

18. The focus ring alignment apparatus of claim 17, wherein
the controller is further configured to extract at least three feature points on the focus ring from the imaged data and then determine an actual position of the focus ring by deriving a circle passing through the at least three feature points, and wherein the controller is configured to control the alignment member to move the focus ring by a deviation between the target position and the actual position on the movement axis.

19. The focus ring alignment apparatus of claim 17, wherein
the controller is further configured to move the alignment member by a separation distance between the alignment member and the focus ring, to stop the alignment member, and then to move the alignment member again.

20. A focus ring alignment apparatus comprising:
a frame comprising a main frame portion having a circular outer circumference, and a support frame portion extending away from the main frame portion;
at least one sensing member connected to the frame and configured to acquire images of a space adjacent the main frame portion;
a plurality of alignment modules connected to the main frame portion, wherein the plurality of alignment modules are in circumferentially spaced apart relationship, and are radially spaced apart from a center of the main frame portion by a preset distance; and
a controller configured to receive imaged data from the at least one sensing member, to extract at least three feature points on a focus ring from the imaged data, to determine a position of the focus ring by deriving a circle passing through the at least three feature points, and to control the plurality of alignment modules to move the focus ring.
